(19) United States
(12) Patent Application Publication
(10) Pub. No.: US 2025/0366144 A1
(43) Pub. Date: Nov. 27, 2025

(54) JUNCTION TEMPERATURE REDUCTION WITH OPTIMIZED GATE TO GATE PITCH

(71) Applicant: SKYWORKS SOLUTIONS, INC., Irvine, CA (US)

(72) Inventors: Yu Zhu, Wellesley, MA (US); Guillaume Alexandre Blin, Carlisle, MA (US)

(21) Appl. No.: 19/213,351

(22) Filed: May 20, 2025

Related U.S. Application Data
(60) Provisional application No. 63/649,977, filed on May 21, 2024.

(51) Int. Cl. H10D 64/27; H01L 23/498; H01L 23/66; H03F 1/02; H03F 3/24; H10D 30/60; H10D 30/67; H10D 86/40

(52) U.S. Cl. CPC H10D 64/518; H01L 23/49811; H01L 23/49827; H01L 23/66; H03F 3/245; H10D 30/611; H10D 30/6758; H10D 64/519; H10D 86/441; H10D 86/481; H03F 1/0216; H03F 2200/451

(57) ABSTRACT

A radio frequency device comprising a semiconductor substrate and a field-effect transistor disposed on the semiconductor substrate. The field-effect transistor includes a plurality of gate fingers that extend parallel in a width dimension. The plurality of gate fingers are spaced apart from each other along a length dimension that is orthogonal to the width dimension with a first gate-to-gate pitch and a second gate-to-gate pitch being different from the first gate-to-gate pitch. The first gate-to-gate pitch may correspond to two adjacent gate fingers arranged at an outer region of the plurality of gate fingers and the second gate-to-gate pitch may correspond to two adjacent gate fingers arranged at an inner region of the plurality of gate fingers, the first gate-to-gate pitch being smaller than the second gate-to-gate pitch. The inner region may arranged closer to a central region of the plurality of gate fingers than the outer region.

### CROSS-REFERENCE TO RELATED APPLICATIONS

This application claims priority under 35 U.S.C. § 119 (e) to U.S. Provisional Patent Application 63/649,977 titled JUNCTION TEMPERATURE REDUCTION WITH OPTIMIZED GATE TO GATE PITCH, filed on May 21, 2024, and hereby incorporated by reference in its entirety for all purposes.

### BACKGROUND

### Technical Field

Aspects and embodiments of the present disclosure generally relate to the field of electronics, and more particularly, to radio frequency (RF) modules and devices.

### Description of Related Technology

An electronic component included in an integrated device die or in an RF module can generate heat during operations. The heat generated by the active device can cause various issues. For example, the heat can negatively impact reliability of the RF module, limit an operating range of the RF module, impact other components in a system or device in which the RF module is included, limit a modulation order and data rate, negatively impact performance (e.g., lower grain, higher leakage, etc.) of the RF module, and negatively impact coverage, data rate, and battery life of the system or device. Accordingly, there remains a desire for improved thermal resistance and reduced junction temperature in integrated device dies or RF modules.

### SUMMARY

The innovations described in the claims each have several aspects, no single one of which is solely responsible for its desirable attributes. Without limiting the scope of the claims, some prominent features of this disclosure will now be briefly described.

Certain aspects of the disclosure pertain to a radio frequency device. The radio frequency device comprises a semiconductor substrate and a field-effect transistor disposed on the semiconductor substrate. The field-effect transistor includes a plurality of gate fingers that extend parallel in a width dimension. The plurality of gate fingers are spaced apart from each other along a length dimension that is orthogonal to the width dimension with a first gate-to-gate pitch and a second gate-to-gate pitch being different from the first gate-to-gate pitch. In the meaning of this disclosure, a gate-to-gate pitch is a distance between two adjacent gate fingers in the length dimension measured at a center line of each gate finger, the center line extending orthogonal to the length dimension.

In some embodiments, the first gate-to-gate pitch corresponds to two adjacent gate fingers arranged at an outer region of the plurality of gate fingers and the second gate-to-gate pitch corresponds to two adjacent gate fingers arranged at an inner region of the plurality of gate fingers, the first gate-to-gate pitch being smaller than the second gate-to-gate pitch. The inner region is arranged closer to a central region of the plurality of gate fingers than the outer region. In particular, a gate-to-gate pitch decreases the further the two adjacent gate fingers are arranged away from a central region of the plurality of gate fingers.

In some embodiments, a ratio of the second gate-to-gate pitch compared to the first gate-to-gate pitch is in the range of about 70/45 to about 70/65.

In some embodiments, gate fingers of the plurality of gate fingers that have the first gate-to-gate pitch have a mirrored configuration with respect to the length dimension. A distance of the plurality of gate fingers can be defined between a first gate finger and a last gate finger of the plurality of gate fingers in the length dimension. In particular, the distance can be measured between a center line of the first gate finger and a center line of the last gate finger both center lines extending orthogonal to the length dimension.

In some embodiments, gate fingers of the plurality of gate fingers that have the second gate-to-gate pitch have a mirrored configuration with respect to the length dimension.

In some embodiments, the plurality of gate fingers is further spaced apart from each other along the length dimension with a third gate-to-gate pitch being different from the first gate-to-gate pitch and from the second gate-to-gate pitch.

In some embodiments, gate fingers of the plurality of gate fingers that have the third gate-to-gate pitch have a mirrored configuration with respect to the length dimension.

Certain further aspects of the disclosure pertain to a radio frequency device. The radio frequency device comprises a semiconductor substrate and a plurality of field-effect transistors disposed in series on the semiconductor substrate. The plurality of field-effect transistors is spaced apart from each other along a length dimension with a first cell-to-cell pitch and a second cell-to-cell pitch being different from the first cell-to-cell pitch. In the meaning of this disclosure, a cell-to-cell pitch is a distance between two gate fingers of adjacent field-effect transistors in the length dimension measured at a center line of each gate finger, the center line extending orthogonal to the length dimension.

In some embodiments, the first cell-to-cell pitch corresponds to two adjacent field-effect transistors arranged at an outer region of the radio frequency device and the second cell-to-cell pitch corresponds to two adjacent field-effect transistors arranged at an inner region of the radio frequency device, the first cell-to-cell pitch being smaller than the second cell-to-cell pitch. The inner region is arranged closer to a central region of the radio frequency device than the outer region. In particular, a cell-to-cell pitch decreases the further the two adjacent field-effect transistors are arranged away from a central region of the radio frequency device.

In some embodiments, field-effect transistors of the plurality of field-effect transistors that have the first cell-to-cell pitch have a mirrored configuration with respect to the length dimension.

In some embodiments, field-effect transistors of the plurality of field-effect transistors that have the second cell-to-cell pitch have a mirrored configuration with respect to the length dimension.

In some embodiments, the plurality of field-effect transistors are further spaced apart from each other along the length dimension with a third cell-to-cell pitch being different from the first cell-to-cell pitch and from the second cell-to-cell pitch.

In some embodiments, gate fingers of the plurality of gate fingers that have the third gate-to-gate pitch have a mirrored configuration with respect to the length dimension.

In some embodiments, each of the plurality of field-effect transistors includes a plurality of gate fingers that extend parallel in a width dimension that is orthogonal to the length dimension, the plurality of gate fingers being spaced apart from each other along the length dimension with a first gate-to-gate pitch and a second gate-to-gate pitch being different from the first gate-to-gate pitch.

Certain further aspects of the disclosure pertain to a radio frequency module. The radio frequency module comprises a packaging substrate configured to receive a plurality of components. The radio frequency module also comprises a transistor stack implemented on the packaging substrate. The transistor stack includes a field-effect transistor disposed on the packaging substrate. The field-effect transistor includes a plurality of gate fingers that extend parallel in a width dimension. The plurality of gate fingers is spaced apart from each other along a length dimension orthogonal to the width dimension with a first gate-to-gate pitch and a second gate-to-gate pitch being different from the first gate-to-gate pitch.

Certain further aspects of the disclosure pertain to another radio frequency module. The radio frequency module comprises a packaging substrate configured to receive a plurality of components. The radio frequency module also comprises a transistor stack implemented on the packaging substrate. The transistor stack includes a plurality of field-effect transistors disposed in series on the packaging substrate. The plurality of field-effect transistors are spaced apart from each other along a length dimension with a first cell-to-cell pitch and a second cell-to-cell pitch being different from the first cell-to-cell pitch.

Certain further aspects of the disclosure pertain to a wireless device. The wireless device comprises a transceiver configured to generate a radio frequency signal. The wireless device further comprises a radio frequency module in communication with the transceiver. The radio frequency module includes a packaging substrate configured to receive a plurality of components. The wireless device further comprises a transistor stack implemented on the packaging substrate. The transistor stack includes a field-effect transistor disposed on the packaging substrate. The field-effect transistor includes a plurality of gate fingers that extend parallel in a width dimension. The plurality of gate fingers are spaced apart from each other along the length dimension with a first gate-to-gate pitch and a second gate-to-gate pitch being different from the first gate-to-gate pitch. Further, the wireless device comprises an antenna in communication with the radio frequency module. The antenna is configured to facilitate transmission of the amplified radio frequency signal.

Certain further aspects of the disclosure pertain to another wireless device. The wireless device comprises a transceiver configured to generate a radio frequency signal. The wireless device further comprises a radio frequency module in communication with the transceiver. The radio frequency module includes a packaging substrate configured to receive a plurality of components. The wireless device further comprises a transistor stack implemented on the packaging substrate. The transistor stack includes a plurality of field-effect transistors disposed in series on the packaging substrate. The plurality of field-effect transistors are spaced apart from each other along a length dimension with a first cell-to-cell pitch and a second cell-to-cell pitch being different from the first cell-to-cell pitch. Further, the wireless device comprises an antenna in communication with the radio frequency module. The antenna is configured to facilitate transmission of the amplified radio frequency signal.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a terminal representation of a Silicon on Insulator (SOI) Field Effect Transistor (FET) according to one or more embodiments of the present disclosure.

FIG. 2 shows a top view schematic diagram of a field effect transistor according to another embodiment.

FIG. 3 shows a plurality of gate fingers that extend parallel in a width dimension.

FIG. 4 shows a graph illustrating a potential relationship between a junction temperature and a gate-to-gate pitch according to another embodiment.

FIG. 5 shows a graph illustrating the potential relationship of FIG. 4 comparing the temperature increase of each gate finger.

FIG. 6 shows a graph illustrating a potential relationship between a junction temperature and a gate-to-gate pitch according to another embodiment comparing the temperature increase of each gate finger.

FIG. 7 shows a plurality of field-effect transistors arranged in series in a length dimension including a plurality of gate fingers that extend parallel according to another embodiment.

FIGS. 8A and 8B show a graph illustrating a potential relationship between a junction temperature and a cell-to-cell pitch according to another embodiment.

FIGS. 9A and 9B show plan and side views, respectively, of a packaged module having one or more features as described herein.

FIG. 10 schematically depicts an example wireless device having one or more advantageous features described herein.

### DETAILED DESCRIPTION

The following detailed description of certain embodiments presents various descriptions of specific embodiments. However, the innovations described herein can be embodied in a multiple of different ways, for example, as defined and covered by the claims. In this description, reference is made to the drawings where like reference numbers can indicate identical or functionally similar elements. It will be understood that elements illustrated in the figures are not necessarily drawn to scale. Moreover, it will be understood that certain embodiments can include more elements than illustrated in a drawing and/or in a subset of the elements illustrated in a drawing. Further, some embodiments can incorporate any suitable combination of features from two or more drawings.

Certain embodiments disclosed herein provide for performance and/or size improvement in transistor stacks using modified transistor finger and/or contact layout, such as in high-performance switch devices/modules. While certain transistor stacks used in switch devices/modules may utilize transistor layouts presenting relatively high aspect ratios, certain embodiments disclosed herein provide for transistor layouts that provide different unit gate widths for different transistors in a transistor stack without requiring increased an aspect ratio to accommodate transistor(s) with longer gate width.

In some implementations, the present disclosure relates to transistor structures and processes that enable a relatively flexible switch layout using transistors of relatively lower aspect ratios, while still maintaining desired switch performance at high frequencies. For example, transistor layouts disclosed herein may comprise transistor fingers rotated approximately 90 degrees with respect to certain conventional transistor layouts. In certain embodiments, rather than summing the drain and source currents at the side edges of the transistor (with respect to the transistor orientation used predominately in the figures associated herewith), the drain and source current sum bars are extended into the transistor. Principles and concepts disclosed herein may advantageously be implemented in connection with Silicon-on-Insulator (SOI) processes. Although certain embodiments are disclosed herein in the context of SOI technologies, it should be understood that the principles disclosed herein may be applicable to other transistor technologies as well. SOI process technology is utilized in many radio-frequency (RF) circuits, including, for example, those involving high performance, low loss, high linearity switches. In such RF switching devices, performance advantages typically result from building a transistor in silicon, which sits on an insulator such as an insulating buried oxide (BOX). The BOX typically sits on a handle wafer, typically silicon, but can alternatively be glass, borosilicon glass, fused quartz, sapphire, silicon carbide, or any other electrically-insulating material.

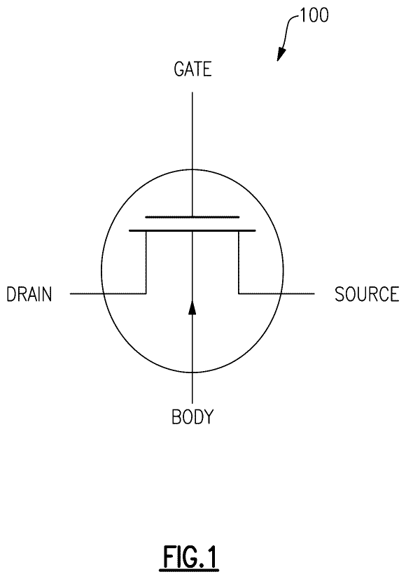

An SOI transistor may be viewed as a 4-terminal field-effect transistor (FET) device with gate, drain, source, and body terminals. FIG. 1 shows an example 4-terminal representation of an SOI FET 100 having nodes associated with a gate, a source, a drain and a body. It will be understood that in some embodiments, the source and the drain nodes can be reversed. Alternatively, an SOI transistor may be viewed as a 5-terminal device, with an addition of a substrate node. Such a substrate node can be biased and/or be coupled to one or more other nodes of the transistor to, for example, improve linearity and/or loss performance of the transistor. Various examples related to SOI and/or other semiconductor active and/or passive devices are described herein in greater detail. Although various examples are described in the context of RF switches, it will be understood that one or more features of the present disclosure can also be implemented in other applications involving FETs and/or other semiconductor devices.

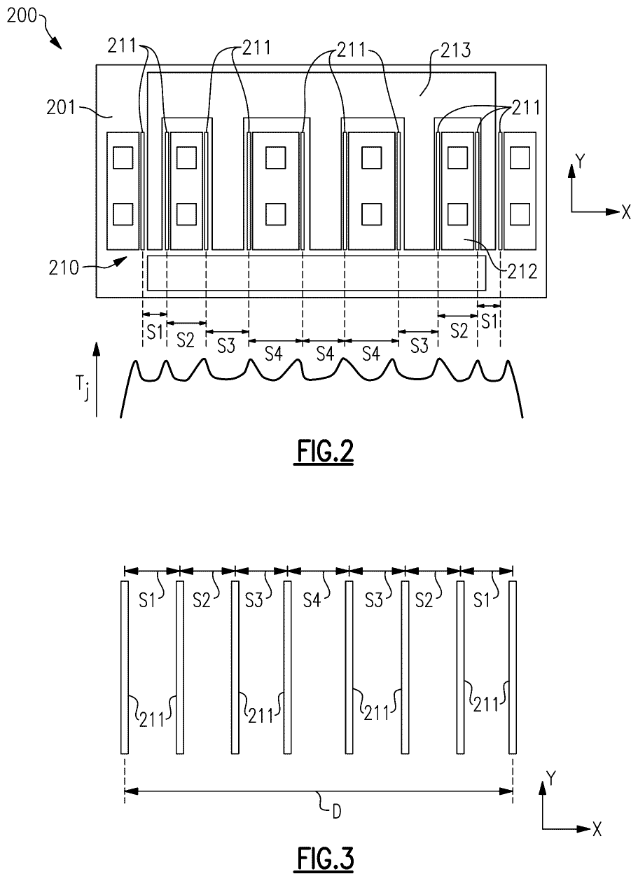

FIG. 2 shows a top view schematic diagram of a field effect transistor 210 according to another embodiment. More specifically, a radio frequency (RF) device 200 comprising a semiconductor substrate 201 and a field-effect transistor 210 disposed on the semiconductor substrate 201 is shown in FIG. 2.

The field-effect transistor 210 includes a plurality of gate fingers 211 that extend parallel in a width dimension Y. The field-effect transistor 210 may further include a plurality of source fingers 212 and a drain 213. Furthermore, the plurality of gate fingers 211 are spaced apart from each other along a length dimension X with a first gate-to-gate pitch S1, a second gate-to-gate pitch S2, a third gate-to-gate pitch S3, or a fourth gate-to-gate pitch S4. The second gate-to-gate pitch S2 is different from the first gate-to-gate pitch S1; the third gate-to-gate pitch S3 is different than the second gate-to-gate pitch S2, the fourth gate-to-gate pitch S4 is different than the third gate-to-gate pitch S3, and the fourth gate-to-gate pitch S4 is different than the first gate-to-gate pitch S1. In other words, the field-effect transistor 210 includes a variable gate spacing, wherein a gate-to-gate pitch in a center of the field-effect transistor 210 can be increased and a gate-to-gate pitch at outer gate fingers can be decreased.

Throughout this disclosure, a gate-to-gate pitch, such as for example the gate-to-gate pitches S1, S2, S3, and S4, is defined to be a distance between two adjacent gate fingers 211 in the length dimension X measured at a center line of each gate finger 211, the center line extending orthogonal to the length dimension X, so here in the Y-axis.

In common field effect transistors with uniform gate-to-gate pitches, a junction temperature Tj at outer gate fingers is lower than the junction temperature at inner gate fingers. As it can be seen below the field effect transistor 210 in FIG. 2, the junction temperature Tj can be reduced at the inner gate fingers by spreading out the inner gate fingers, wherein the gate-to-gate pitch at the outer gate fingers is reduced. Hence, the field effect transistor 210 and the RF device 200, respectively, can have the same size compared to a common field effect transistor having a uniform gate-to-gate pitch. In particular, the junction temperature at all gate fingers 211 of the field effect transistor 210 can substantially have the same value.

Advantageously, the junction temperature can be reduced by optimizing the gate-to-gate pitch without increasing the die area. Exemplarily, the first gate-to-gate pitch S1 corresponds to two adjacent gate fingers 211 arranged at an outer region of the plurality of gate fingers and the second gate-to-gate pitch S2 corresponds to two adjacent gate fingers 211 arranged at an inner region of the plurality of gate fingers. Thereby, the first gate-to-gate pitch S1 is smaller than the second gate-to-gate pitch S2. The inner region is arranged closer to a central region of the plurality of gate fingers 211 than the outer region.

In particular, a gate-to-gate pitch decreases the further the two adjacent gate fingers 211 are arranged away from a central region of the plurality of gate fingers. Consequently, the gate-to-gate pitch S1 is smaller than the gate-to-gate pitch S2, S3 and S4 here. The gate-to-gate pitch S2 is smaller than the gate-to-gate pitch S3 and S4 according to FIG. 2. Also, the gate-to-gate pitch S3 is smaller than the gate-to-gate pitch S4.

Further, gate fingers 211 of the plurality of gate fingers 211 that have the first gate-to-gate pitch S1 can have a mirrored configuration with respect to the length dimension X. Alternatively or additionally, gate fingers 211 of the plurality of gate fingers that have the second gate-to-gate pitch S2 can have a mirrored configuration with respect to the length dimension X.

Furthermore, the plurality of gate fingers 211 can be further spaced apart from each other along the length dimension X with a third gate-to-gate pitch S3 or S4. The third gate-to-gate pitch S3 or S4 is different from the first gate-to-gate pitch S1 and from the second gate-to-gate pitch S2. Optionally, gate fingers 211 of the plurality of gate fingers that have the third gate-to-gate pitch S3 or S4 can have a mirrored configuration with respect to the length dimension X.

FIG. 3 shows a plurality of gate fingers 211 that extend parallel in a width dimension Y.

Here, eight gate fingers 211 are illustrated, wherein the eight gate fingers 211 have a distance D. The distance D of the plurality of gate fingers 211 can be defined between a first gate finger and a last gate finger of the plurality of gate fingers in the length dimension X. In particular, the distance D can be measured between a center line of the first gate finger and a center line of the last gate finger, both center lines extending orthogonal to the length dimension X so in Y-axis.

The eight gate fingers 211 are spaced apart from each other with a first gate-to-gate pitch S1, a second gate-to-gate pitch S2, a third gate-to-gate pitch S3 and a fourth gate-to-gate pitch S4. The gate-to-gate pitch S1 is smaller than the second, third and fourth gate-to-gate pitch S2, S3 and S4. The second gate-to-gate pitch S2 is smaller than the third and the fourth gate-to-gate pitch S3 and S4. Also, the third gate-to-gate pitch S3 is smaller than the fourth gate-to-gate pitch S4. Moreover, the eight gate fingers 211 have a mirrored configuration with respect to the length dimension X. That means, starting from the center of the eight gate fingers 211, each sequence of gate fingers towards the first and the last gate finger, respectively, of the gate fingers 211 in the length dimension X has the same gate-to-gate pitches S3, S2 and S1. In a mathematical expression, the fourth gate-to-gate pitch S4 can be calculated as S4=D−2*(S1+S2+S3).

A length of each gate finger 211 can be 0.15 micrometers, for example. An objective function for a temperature increase of the junction temperature of gate fingers can be dependent on the first, second and third gate-to-gate pitch S1, S2 and S3 for example.

In some embodiments, an increasing gate width makes the gate-to-gate pitch in the central region, in particular the fourth gate-to-gate pitch S4, larger, wherein other parameters like the distance D are maintained.

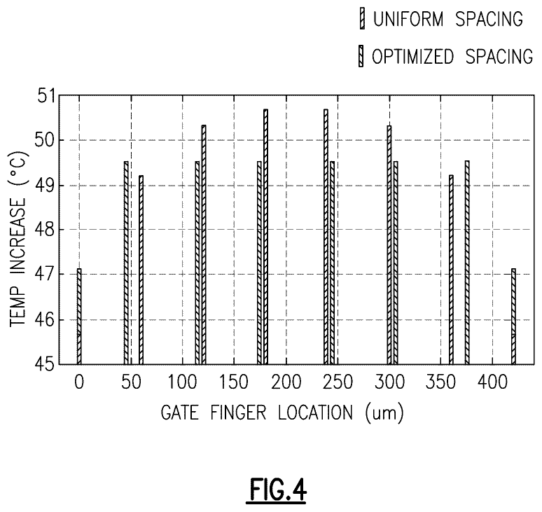

FIG. 4 shows a graph illustrating a potential relationship between a junction temperature Tj and a gate-to-gate pitch according to another embodiment. More specifically, the graph illustrates a gate finger location in the length dimension X with the unit micrometers (um) in relation to a temperature increase of the junction temperature Tj of the gate fingers 211 with the unit degree Celsius (° C.). Thereby, the temperature increase of a common field-effect transistor with uniform gate spacing is compared to a field-effect transistor 210 with variable gate spacing according to an embodiment of the invention.

Exemplarily, a first gate-to-gate pitch corresponds to two adjacent gate fingers 211 arranged at an outer region of the plurality of gate fingers, so at the right or left end of the graph, and a second gate-to-gate pitch corresponds to two adjacent gate fingers 211 arranged at an inner region of the plurality of gate fingers. Thereby, the first gate-to-gate pitch is smaller than the second gate-to-gate pitch. The inner region is arranged closer to a central region of the plurality of gate fingers 211 than the outer region. The central region here in the graph lies at a gate finger location of about 210 um, corresponding to 0.5 D with D=420 um.

For example, a ratio of the second gate-to-gate pitch compared to the first gate-to-gate pitch can be in the range of about 70/45 to about 70/65.

Here, the plurality of gate fingers includes eight gate fingers 211. A gate width of the gate fingers 211 can be 200 μm, for example. The semiconductor substrate can have a thickness of 100 um. A base temperature can be 125° C., wherein a power density could be 5 W/mm, for example.

FIG. 5 shows a graph illustrating the potential relationship of FIG. 4 comparing the temperature increase of each gate finger. More specifically, the graph illustrates a gate finger number in relation to a temperature increase of the junction temperature Tj of the gate fingers 211 with the unit degree Celsius (° C.). Thereby, the temperature increase of a common field-effect transistor with uniform gate spacing is compared to a field-effect transistor 210 with variable gate spacing according to an embodiment of the present disclosure.

The gate-to-gate pitches of the gate fingers 211 are adjusted such that the temperature increase is optimized, wherein the distance D and a die area, respectively, is maintained. In particular, a peak temperature increase in the central region (gate finger numbers 4 and 5) can be reduced by the field-effect transistor according to FIGS. 2, 3 and 4.

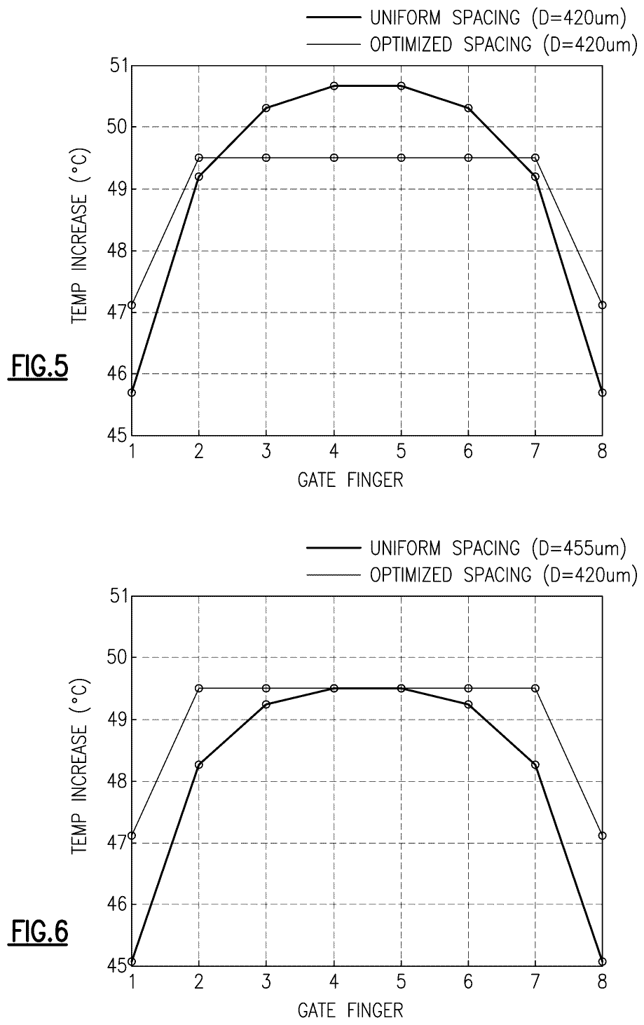

FIG. 6 shows a graph illustrating a potential relationship between a junction temperature and a gate-to-gate pitch according to another embodiment comparing the temperature increase of each gate finger. More specifically, the graph illustrates a gate finger number in relation to a temperature increase of the junction temperature Tj of the gate fingers 211 with the unit degree Celsius (° C.). Thereby, the temperature increase of a common field-effect transistor with uniform gate spacing is compared to a field-effect transistor 210 with variable gate spacing according to an embodiment of the invention.

In FIG. 6, it is emphasized that the distance D would need to be increased when having a common uniform gate spacing of gate fingers in order to reduce the peak temperature increase to the level of the optimized gate spacing according to an embodiment of the invention. Here, the distance D originally having 420 um needs to be increased to 455 um for limiting the peak temperature in the central region to the level of the optimized gate spacing according to an embodiment of the invention. By increasing the distance D a die area would also be increased.

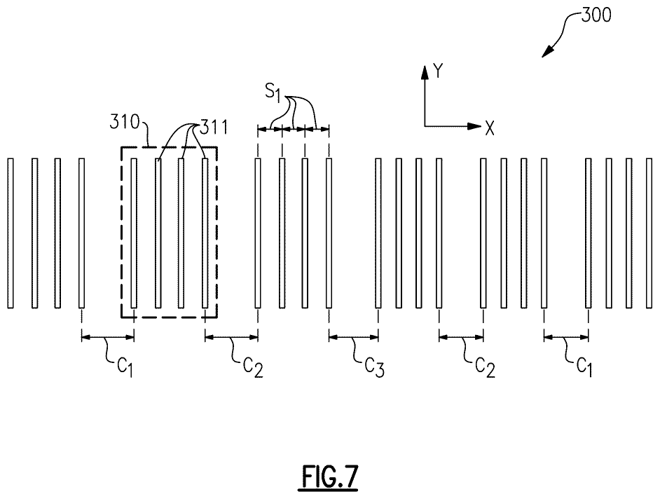

FIG. 7 shows a plurality of field-effect transistors 310 arranged in series in a length dimension X including a plurality of gate fingers 311 that extend parallel according to another embodiment. More specifically, a radio frequency (RF) device 300 comprising a semiconductor substrate and a plurality of field-effect transistors 310 disposed in series on a semiconductor substrate such as that shown in FIG. 2.

Each field-effect transistor 310 can also be a unit cell. The plurality of field-effect transistors 310 are spaced apart from each other along the length dimension X with a first cell-to-cell pitch C1 and a second cell-to-cell pitch C2. The second cell-to-cell pitch C2 is different from the first cell-to-cell pitch C1. In other words, the RF device 300 includes a variable FET spacing, wherein a cell-to-cell pitch in a center of the RF device 300 can be increased and a cell-to-cell pitch at outer field-effect transistors 310 can be decreased. In the meaning of this disclosure, a cell-to-cell pitch C1, C2, C3 is a distance between two gate fingers 311 of adjacent field-effect transistors 310 in the length dimension X measured at a center line of each gate finger 311, the center line extending orthogonal to the length dimension X, so in the Y-axis.

For example, the first cell-to-cell pitch C1 can correspond to two adjacent field-effect transistors 310 arranged at an outer region of the radio frequency device 300 and the second cell-to-cell pitch C2 can correspond to two adjacent field-effect transistors 310 arranged at an inner region of the radio frequency device 300. The first cell-to-cell pitch C1 can be smaller than the second cell-to-cell pitch C2. The inner region is arranged closer to a central region of the radio frequency device 300 than the outer region. In particular, a cell-to-cell pitch decreases the further the two adjacent field-effect transistors are arranged away from a central region of the radio frequency device 300. Here, the radio frequency device 300 includes six field-effect transistors 310 or unit cells, respectively.

Optionally, field-effect transistors 310 of the plurality of field-effect transistors that have the first cell-to-cell pitch C1 can have a mirrored configuration with respect to the length dimension X. Alternatively or additionally, field-effect transistors 310 of the plurality of field-effect transistors that have the second cell-to-cell pitch C2 can have a mirrored configuration with respect to the length dimension C2.

Further, the plurality of field-effect transistors 310 can be further spaced apart from each other along the length dimension X with a third cell-to-cell pitch C3. The third cell-to-cell pitch C3 is different from the first cell-to-cell pitch C1 and from the second cell-to-cell pitch C2.

Each of the plurality of field-effect transistors 310 can include a plurality of gate fingers 311 that extend parallel in the width dimension Y. In FIG. 7, the plurality of gate fingers 311 have a first gate-to-gate pitch S1 of about 32 um, for example. Optionally, the plurality of gate fingers 311 may be spaced apart from each other along the length dimension X with the first gate-to-gate pitch S1 and a second gate-to-gate pitch (not shown) being different from the first gate-to-gate pitch S1.

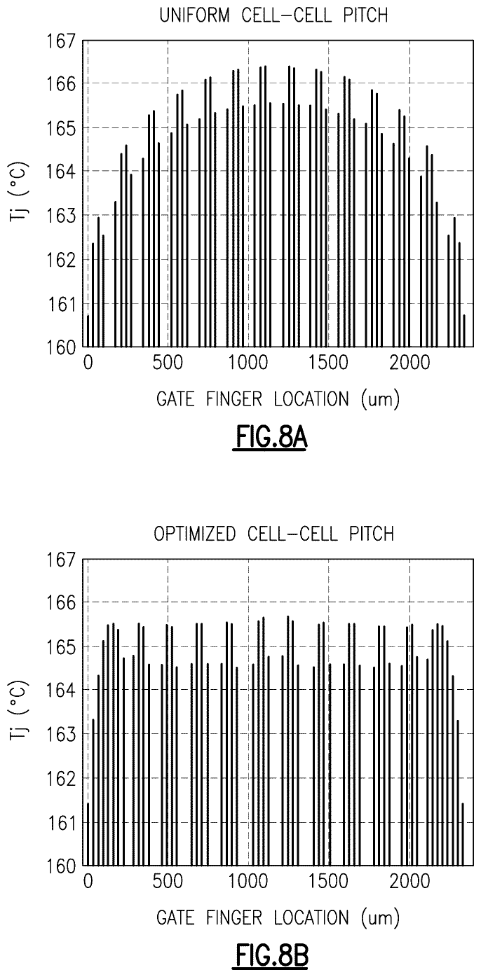

FIGS. 8A and 8B show graphs illustrating a potential relationship between a junction temperature Tj and a cell-to-cell pitch according to another embodiment. More specifically, both graphs illustrate a gate finger location in the length dimension X with the unit micrometers (um) in relation to the junction temperature Tj of the gate fingers 311 with the unit degree Celsius (° C.). Thereby, the RF device of FIG. 8A has a common uniform cell-to-cell pitch, wherein the RF device 300 of FIG. 8B has a variable cell-to-cell pitch according to an embodiment of the invention.

Here, the plurality of field-effect transistors includes fourteen field-effect transistors 310. A gate width of the gate fingers 311 can be 200 um, for example. The common uniform cell-to-cell pitch can be 77 um, for example. The semiconductor substrate can have a thickness of 100 um. A base temperature can be 135° C., wherein a power density could be 2.58 W/mm, for example.

In comparison of FIGS. 8A and 8B, a thermal resistance Rth can be reduced by 2.4%.

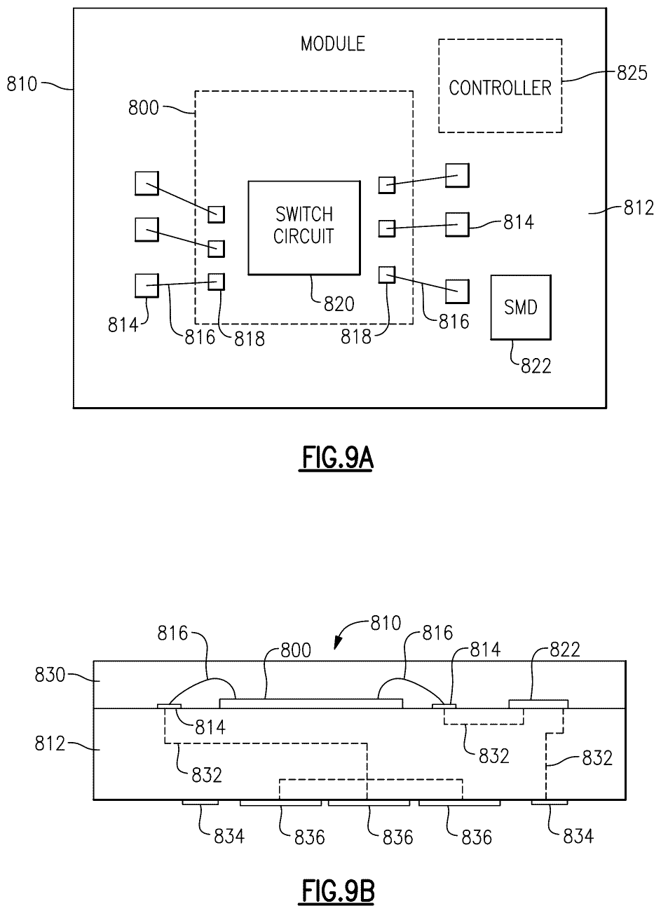

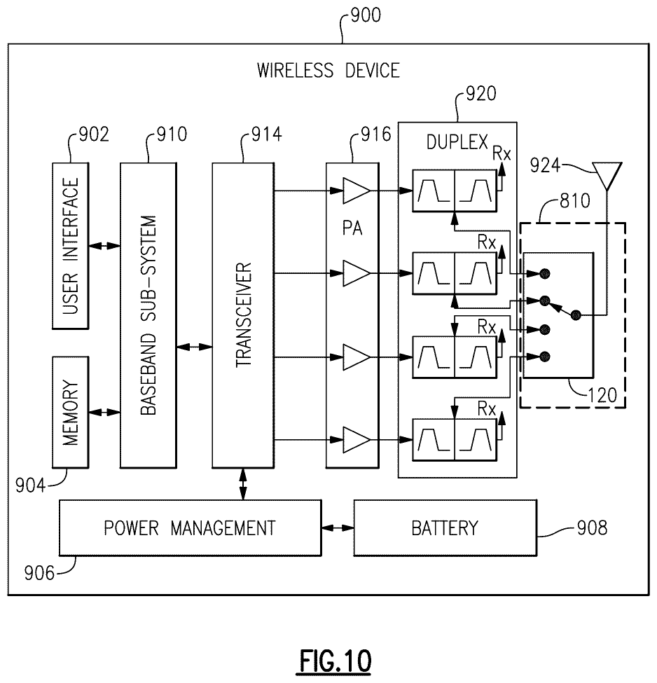

In some embodiments, one or more die having one or more features described herein can be implemented in a packaged module. An example of such a module is shown in FIGS. 9A (plan view) and 9B (side view). A module 810 is shown to include a packaging substrate 812. Such a packaging substrate can be configured to receive a plurality of components, and can include, for example, a laminate substrate. The components mounted on the packaging substrate 812 can include one or more dies. In the example shown, a die 800 having integrated active and passive devices, as described herein, is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 832 is depicted as interconnecting the SMD 822 with an external-connection contact pad 834. In yet another example a connection path 832 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 10 schematically depicts an example wireless device 900 having one or more advantageous features described herein. In the context of various switches as described herein, a switch 120 can be part of a module 810, wherein the switch 120 may comprise low aspect ratio transistor switches according to one or more embodiments disclosed herein. Furthermore, other components of the device 900 may include integrated active/passive dic(s) as described herein, such as the power amplifier module 916, duplexer 920 and/or other components or combinations thereof. In some embodiments, the switch module 810 can facilitate, for example, multi-band multi-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in known manners. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 810.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 10, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the present disclosure is not intended to be exhaustive or to limit the disclosure to the precise form disclosed above.

While specific embodiments and examples are described above for illustrative purposes, various equivalent modifications are possible within the scope of the disclosure, as those skilled in the relevant art will recognize.

The teaching of the present disclosure provided herein can be applied to other systems, not necessarily the system described above. The elements and various embodiments described above can be combined to provide further embodiments.

While certain embodiments have been described, these embodiments have been presented by way of example only, and are not intended to limit the scope of the disclosure. Indeed, the device and system described herein may be embodied in a variety of other forms. Furthermore, various omissions, substitutions and changes in the form of the system described herein may be made without departing from the spirit of the disclosure. The accompanying claims and the equivalents are intended to cover such forms or modifications as would fall within the scope and spirit of the disclosure.

What is claimed is:

1. A radio frequency device, comprising:
a semiconductor substrate; and
a field-effect transistor disposed on the semiconductor substrate, the field-effect transistor including a plurality of gate fingers that extend parallel in a width dimension, the plurality of gate fingers being spaced apart from each other along a length dimension that is orthogonal to the width dimension with a first gate-to-gate pitch and a second gate-to-gate pitch being different from the first gate-to-gate pitch.

2. The radio frequency device of claim 1 wherein the first gate-to-gate pitch corresponds to two adjacent gate fingers arranged at an outer region of the plurality of gate fingers and the second gate-to-gate pitch corresponds to two adjacent gate fingers arranged at an inner region of the plurality of gate fingers, the first gate-to-gate pitch being smaller than the second gate-to-gate pitch.

3. The radio frequency device of claim 2 wherein a ratio of the second gate-to-gate pitch compared to the first gate-to-gate pitch is in the range of about 70/45 to about 70/65.

4. The radio frequency device of claim 1 wherein gate fingers of the plurality of gate fingers that have the first gate-to-gate pitch have a mirrored configuration with respect to the length dimension.

5. The radio frequency device of claim 1 wherein gate fingers of the plurality of gate fingers that have the second gate-to-gate pitch have a mirrored configuration with respect to the length dimension.

6. The radio frequency device of claim 1 wherein the plurality of gate fingers is further spaced apart from each other along the length dimension with a third gate-to-gate pitch being different from the first gate-to-gate pitch and from the second gate-to-gate pitch.

7. The radio frequency device of claim 1 wherein gate fingers of the plurality of gate fingers that have the third gate-to-gate pitch have a mirrored configuration with respect to the length dimension.

8. A radio frequency device, comprising:
a semiconductor substrate; and
a plurality of field-effect transistors disposed in series on the semiconductor substrate, the plurality of field-effect transistors being spaced apart from each other along a length dimension with a first cell-to-cell pitch and a second cell-to-cell pitch being different from the first cell-to-cell pitch.

9. The radio frequency device of claim 8 wherein the first cell-to-cell pitch corresponds to two adjacent field-effect transistors arranged at an outer region of the radio frequency device and the second cell-to-cell pitch corresponds to two adjacent field-effect transistors arranged at an inner region of the radio frequency device, the first cell-to-cell pitch being smaller than the second cell-to-cell pitch.

10. The radio frequency device of claim 8 wherein field-effect transistors of the plurality of field-effect transistors that have the first cell-to-cell pitch have a mirrored configuration with respect to the length dimension.

11. The radio frequency device of claim 8 wherein field-effect transistors of the plurality of field-effect transistors that have the second cell-to-cell pitch have a mirrored configuration with respect to the length dimension.

12. The radio frequency device of claim 8 wherein the plurality of field-effect transistors is further spaced apart from each other along the length dimension with a third cell-to-cell pitch being different from the first cell-to-cell pitch and from the second cell-to-cell pitch.

13. The radio frequency device of claim 8 wherein each of the plurality of field-effect transistors includes a plurality of gate fingers that extend parallel in a width dimension, the plurality of gate fingers being spaced apart from each other along the length dimension with a first gate-to-gate pitch and a second gate-to-gate pitch being different from the first gate-to-gate pitch.

14. The radio frequency module of claim 13 wherein the first gate-to-gate pitch corresponds to two adjacent gate fingers arranged at an outer region of the plurality of gate fingers and the second gate-to-gate pitch corresponds to two adjacent gate fingers arranged at an inner region of the plurality of gate fingers, the first gate-to-gate pitch being smaller than the second gate-to-gate pitch.

15. The radio frequency module of claim 14 wherein a ratio of the second gate-to-gate pitch compared to the first gate-to-gate pitch is in the range of about 70/45 to about 70/65.

16. The radio frequency module of claim 13 wherein gate fingers of the plurality of gate fingers that have the first gate-to-gate pitch have a mirrored configuration with respect to the length dimension.

17. The radio frequency module of claim 13 wherein gate fingers of the plurality of gate fingers that have the second gate-to-gate pitch have a mirrored configuration with respect to the length dimension.

18. The radio frequency module of claim 13 wherein the plurality of gate fingers is further spaced apart from each other along the length dimension with a third gate-to-gate pitch being different from the first gate-to-gate pitch and from the second gate-to-gate pitch.

19. The radio frequency module of claim 13 wherein gate fingers of the plurality of gate fingers that have the third gate-to-gate pitch have a mirrored configuration with respect to the length dimension.
